(19) United States
(12) Patent Application Publication
(10) Pub. No.: US 2026/0202453 A1
(43) Pub. Date: Jul. 16, 2026

(54) LOW-AMPLITUDE INDUCED LIGHTNING HAZARD ASSESSMENT METHOD FOR DISTRIBUTION NETWORK

(71) Applicant: Kunming University of Science and Technology, Kunming (CN)

(72) Inventors: Hongchun SHU, Kunming (CN); Yutao TANG, Kunming (CN); Ying CAO, Kunming (CN); Yiming HAN, Kunming (CN); Weijie LOU, Kunming (CN); Yue DAI, Kunming (CN)

(73) Assignee: Kunming University of Science and Technology, Kunming (CN)

(21) Appl. No.: 19/062,097

(22) Filed: Feb. 25, 2025

(30) Foreign Application Priority Data
Jan. 14, 2025 (CN) 202510056045.9

(51) Int. Cl. G01R 29/08; G08B 21/10

(52) U.S. Cl. CPC G01R 29/0842; G08B 21/10

(57) ABSTRACT

A low-amplitude induced lightning hazard assessment method for distribution networks includes: calculating tower height h for each line in the distribution network and soil resistivity ρ of each area, and inputting h and ρ into the corresponding data of each tower in a distribution network lightning detection system; calculating a resistance coefficient k of each tower and inputting k into the corresponding data of each tower in the distribution network lightning detection system; partitioning a lightning-induced overvoltage amplitude U based on severity of hazard and assigning different colors to each partition, and setting a dangerous overvoltage threshold Uₛₑₜ; real time detection of cloud-to-ground lightning and calculating the lightning-induced overvoltage amplitude U of the cloud-to-ground lightning; if U≥Uₛₑₜ, the system issues a warning; if U<Uₛₑₜ, no warning is required; marking the cloud-to-ground lightning on the distribution network area map according to different hazard levels indicated by the colors.

### CROSS REFERENCE TO THE RELATED APPLICATIONS

This application is based upon and claims priority to Chinese Patent Application No. 202510056045.9, filed on Jan. 14, 2025, the entire contents of which are incorporated herein by reference.

### TECHNICAL FIELD

The present invention relates to a low-amplitude induced lightning hazard assessment method for a distribution network, belonging to the field of power system lightning protection.

### BACKGROUND

Lightning strikes with current amplitudes below 15 kA are classified as low-amplitude lightning, characterized by weak electromagnetic signal strengths, which makes them challenging to detect using conventional lightning location systems. However, in certain regions, newly implemented high-precision distribution network lightning detection systems are capable of detecting these lightning strikes and providing information such as lightning current amplitude and strike location. Occurrence of low-amplitude cloud-to-ground lightning is relatively frequent, and since insulation strength of the distribution network is not high, faults often occur due to such low-amplitude cloud-to-ground lightning. Lightning can cause faults in distribution lines through two primary mechanisms: lightning strikes on the distribution lines, generating direct overvoltage, and induced overvoltage resulting from lightning strikes on the ground and structures near the lines, which accounts for approximately 80% of lightning-related faults.

When a lightning strike occurs near a distribution line, if the induced overvoltage generated by the line exceeds its insulation level, insulation breakdown will occur. A waveform of induced overvoltage is relatively smooth, with a wavefront duration ranging from a few microseconds to several tens of microseconds, and wavelengths reaching several hundred microseconds. The characteristics of lightning overvoltage in distribution lines are as follows: 1) The amplitude of lightning-induced overvoltage increases as the distance between the accumulation point and the distribution line decreases, with a greater increase in amplitude as the distance shortens; 2) The amplitude of lightning-induced overvoltage increases with the height of the tower; 3) The amplitude of lightning-induced overvoltage increases with the increase in lightning current amplitude; 4) The amplitude of lightning-induced overvoltage increases with the increase in ground resistivity. The detailed calculation of induced lightning is relatively complex, and in engineering practice, the maximum induced overvoltage amplitude on a conductor is generally approximated using the formula (1) recommended by standards, where I represents a lightning current amplitude, h denotes a tower height, and S represents a distance between the lightning strike point and the tower.

$$U = 25 \frac{h}{D} I \qquad ( 1 )$$

### SUMMARY

Low-amplitude cloud-to-ground lightning represent a major threat to the safe and reliable operation of distribution networks. Currently, the detection of low-amplitude cloud-to-ground lightning mainly relies on manual line inspection, with the assistance of various fault recording data and fault trip information to locate specific information on low-amplitude cloud-to-ground lightning and evaluate their overvoltage hazards. Moreover, when using the formula (1) recommended by the standards to approximate the maximum induced overvoltage on the conductor, the effect of soil resistivity is not taken into account, which significantly reducing its applicability in high-resistivity soil areas, such as mountainous regions or deserts.

To address the limitations of existing methods for assessing the overvoltage hazards caused by low-amplitude cloud-to-ground lightning in distribution networks, the present invention provides a method for assessing the hazards of low-amplitude lightning-induced overvoltage in distribution networks, the specific steps of which are:
Step 1: collecting a tower height h for each of lines in the distribution network and a soil resistivity ρ of areas where the lines are located, wherein h and ρ are input into corresponding data of each tower in a distribution network lightning detection system;
Step 2: according to the formula:

$$k = [ 25 + 0.075 ( ρ - 300 ) ] h \qquad ( 2 )$$

wherein k represents a resistance coefficient of a relationship between a lightning-induced overvoltage and a lightning current amplitude in distribution lines, and k is input into corresponding data of each tower in the distribution network lightning detection system;

The resistance coefficient k is a modified value of the coefficient in the recommended calculation formula for lightning-induced overvoltage, which takes into account the effect of soil resistivity on lightning-induced overvoltage, in addition to the considerations of the standard formula. The basis is that the soil resistivity in the area where the regulations formula (1) is applicable is 300 Ω·m, and the grounding resistance should not exceed 10Ω, while in areas with high soil resistivity such as mountains and deserts, the resistivity should reach 1000 Ω·m, and the grounding resistance should not exceed 30Ω. Based on the above two sets of data, the ratio of grounding resistance to soil resistivity is about 0.03; After lightning strikes the ground, only a portion flows towards the tower and the line through the grounding body. The shunt coefficient can be approximated as 5 h/2D according to formula (1). Therefore, the overvoltage amplitude correction can be calculated as shown in formula (3), resulting in the corrected lightning-induced overvoltage amplitude calculation formula considering soil resistivity, as shown in formula (4):

$$Δ U = 0.03 \frac{5 h}{2 D} ( ρ - 300 ) I \qquad ( 3 )$$

$$U = [ 25 + 0.075 ( ρ - 300 ) ] \frac{h}{D} I \qquad ( 4 )$$

The resistance coefficient k can also be modified using other equivalent methods or further corrected by considering other influencing factors.
Step 3: partitioning a lightning-induced overvoltage amplitude U based on severity of hazard and assigning different colors to each partition, wherein a dangerous overvoltage threshold Uₛₑₜ is set for dangerous overvoltage;

The partition is mainly based on severity of hazard, including voltage level, insulation strength, and specific operation and maintenance conditions of a distribution network, with partition density and effectiveness depending on specific circumstances.
Step 4: when the distribution network lightning detection system detects the cloud-to-ground lightning, calculating the lightning-induced overvoltage amplitude U of the cloud-to-ground lightning using the following formula;

$$U = \frac{k}{D} I \qquad ( 5 )$$

The setting of the dangerous overvoltage threshold in Step 3 is not uniform across an entire line, and towers with weak insulation should be considered separately.
Step 5: if U≥Uₛₑₜ, indicating that a cloud-to-ground lightning poses a serious threat to safety of the lines and equipment, and the distribution network lightning detection system issues a warning to remind a maintenance personnel to pay close attention to the cloud-to-ground lightning and nearby lines and equipment; if U<Uₛₑₜ, indicating that a hazard level of the cloud-to-ground lightning is relatively low and no warning is required;

Issuing of a warning is proportional to the extent to which an overvoltage exceeds a dangerous overvoltage threshold.
Step 6: marking the cloud-to-ground lightning on a distribution network area map in the distribution network lightning detection system according to the different severity of hazard indicated by the colors in Step 3, for review by the maintenance personnel.

This invention can also utilize other human-machine interaction method to retrieve information.

### The Implementation of this Invention has the Following Beneficial Effects

1. By integrating with the distribution network lightning detection system, information on low-amplitude cloud-to-ground lightning, lightning-induced overvoltage, and severity of hazard can be obtained through human-computer interaction, significantly enhancing the efficiency of operation and maintenance personnel.

2. The calculation formula for lightning-induced overvoltage in the regulations has been revised by incorporating soil resistivity, enhancing its applicability in regions with high soil resistivity.

3. It facilitates the observation of patterns of low-amplitude cloud-to-ground lightning and its associated hazards within the statistical area, providing valuable data support for the intelligent transformation of the distribution network.

### BRIEF DESCRIPTION OF THE DRAWINGS

In order to more clearly explain the examples of the present invention or the technical solutions in the prior art, a brief introduction to the accompanying drawings required for the description of these examples or prior art will be provided. It is evident that the accompanying drawings described below are merely illustrative examples of the present invention, and a person skilled in the art could, without inventive effort, derive other drawings based on these.

FIG. 1 is a flowchart of the method of the present invention;

FIG. 2 is a diagram showing the distribution network area marked with the degree of cloud-to-ground lightning hazard within a range of D≤100 m according to an example of the present invention;

FIG. 3 is a diagram showing the distribution network area marked with the degree of cloud-to-ground lightning hazard within a range of D≤500 m according to another example of the present invention.

### DETAILED DESCRIPTION OF THE EMBODIMENTS

The present invention will be further explained in conjunction with the accompanying drawings and specific embodiments. Obviously, the described embodiments are only part of the embodiments of the present invention, not all of them. Based on the embodiments of the present invention, all other embodiments that can be derived by a person skilled in the art without inventive effort are within the scope of the present invention's protection.

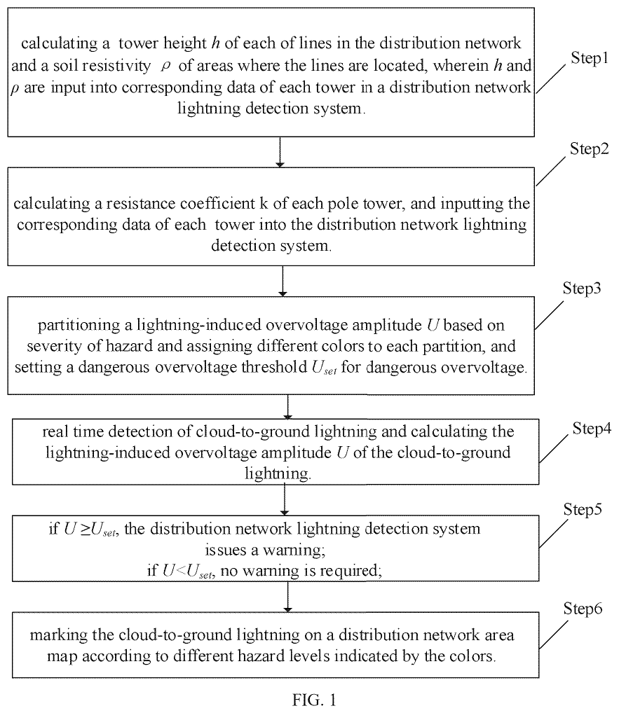

Example: as shown in FIGS. 1-3, in the distribution network lightning detection system, the method of the present invention, “a low-amplitude induced lightning hazard assessment method for a distribution network” is used to analyze severity of hazard to the distribution network in a high-incidence area of low-amplitude cloud-to-ground lightning in a certain county, and the specific implementation steps are as follows:

Step 1: collecting a tower height h for each of lines in the distribution network and a soil resistivity ρ of areas where the lines are located, wherein h and ρ are input into corresponding data of each tower in a distribution network lightning detection system, wherein the tower heights are 7 m, 9 m, and 12 m, and the soil resistivity ranges from 800 to 1000 Ω·m;
Step 2: according to the formula:

$$k = [ 25 + 0.075 ( ρ - 300 ) ] h \qquad ( 2 )$$

The resistance coefficient k represents the relationship between lightning-induced overvoltage and lightning current amplitude in distribution lines is shown in the table below, and input the resistance coefficient k into the corresponding data of each tower in the distribution network lightning detection system.

TABLE 1
Resistance coefficient k in the implementation example

| | | Soil resistivity | | | | |
|---|---|---|---|---|---|---|
| | | 800 | 850 | 900 | 950 | 1000 |
| Tower height | | Ω · m | Ω · m | Ω · m | Ω · m | Ω · m |
| 7 | m | 437.5 | 463.75 | 490 | 516.25 | 542.5 |
| 9 | m | 562.5 | 596.25 | 630 | 663.75 | 697.5 |
| 12 | m | 750 | 795 | 840 | 885 | 930 |

Step 3: partitioning a lightning-induced overvoltage amplitude U based on severity of hazard and assigning different colors to each partition, wherein a dangerous overvoltage threshold Uₛₑₜ=80 kV is set for dangerous overvoltage;
Step 4: according to the formula:

$$U = \frac{k}{D} I \qquad ( 5 )$$

calculating the lightning-induced overvoltage amplitude U caused by cloud-to-ground lightning, based on the lightning data detected by the distribution network lightning detection system within the distribution line corridor of a radius of 100 m (i.e., D≤100 m);
Step 5: if U≥Uₛₑₜ, indicating that a cloud-to-ground lightning poses a serious threat to safety of lines and equipment, and the distribution network lightning detection system issues a warning to remind a maintenance personnel to pay close attention to the cloud-to-ground lightning and nearby lines and equipment; if U<Uₛₑₜ, indicating that a hazard level of the cloud-to-ground lightning is relatively low and no warning is required; with the example directly processing the existing lightning data, skipping this step.
Step 6: marking the cloud-to-ground lightning on the distribution network area map in the distribution network lightning detection system according to different hazard levels indicated by the colors in Step 3, for review by the maintenance personnel;

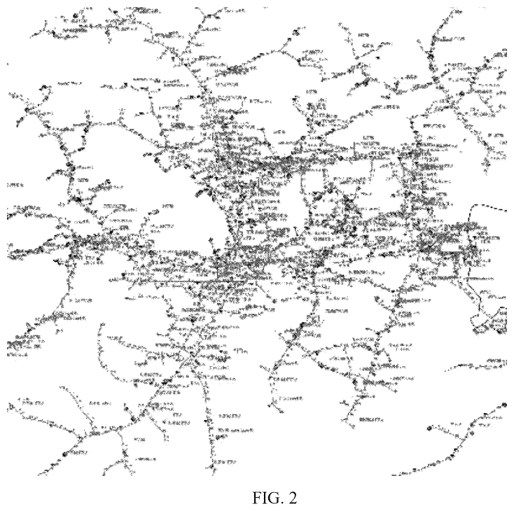

FIG. 2 shows a partial diagram of the marked distribution network area (the original image is in color). Overall, there are 8102 dangerous cloud-to-ground lightning within the range of D≤100 m;

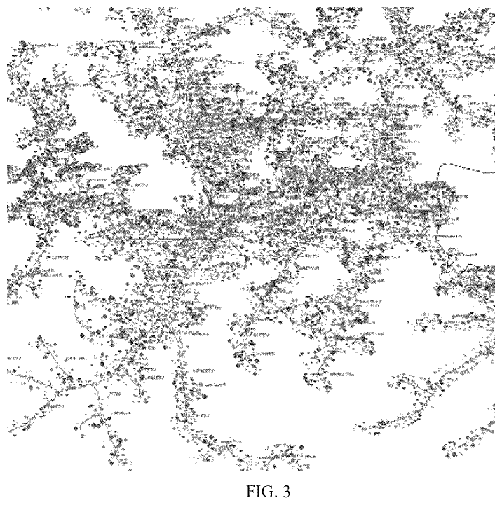

Take the lightning data detected by the lightning detection system of the distribution network within the range of D≤500 m, repeat steps 4 and 6, and obtain the marked distribution network area map. Some of the maps are shown in FIG. 3 (the original image is colored). Overall, there are 36775 dangerous cloud-to-ground lightning within the range of D≤500 m.

1. A low-amplitude induced lightning hazard assessment method for a distribution network, comprising the following steps:
Step 1: collecting a tower height h for each of lines in the distribution network and a soil resistivity ρ of areas where the lines are located, wherein h and ρ are input into corresponding data of each tower in a distribution network lightning detection system;
Step 2: according to the formula:
$$k = [ 25 + 0.075 ( ρ - 300 ) ] h \qquad ( 1 )$$
wherein k represents a resistance coefficient of a relationship between a lightning-induced overvoltage and a lightning current amplitude in distribution lines, and k is input into corresponding data of each tower in the distribution network lightning detection system;
Step 3: partitioning a lightning-induced overvoltage amplitude U based on severity of hazard and assigning different colors to each partition, wherein a dangerous overvoltage threshold Uₛₑₜ is set for dangerous overvoltage;
Step 4: when the distribution network lightning detection system detects a cloud-to-ground lightning, calculating the lightning-induced overvoltage amplitude U of the cloud-to-ground lightning using the following formula;
$$U = \frac{k}{D} I \qquad ( 2 )$$
Step 5: if U≥Uₛₑₜ, indicating that a cloud-to-ground lightning poses a serious threat to safety of the lines and equipment, and the distribution network lightning detection system issues a warning to remind a maintenance personnel to pay close attention to the cloud-to-ground lightning and nearby lines and equipment; if U<Uₛₑₜ, indicating that a hazard level of the cloud-to-ground lightning is relatively low and no warning is required; and
Step 6: marking the cloud-to-ground lightning on a distribution network area map in the distribution network lightning detection system according to different hazard levels indicated by the colors in Step 3, for review by the maintenance personnel.

2. The low-amplitude induced lightning hazard assessment method for the distribution network according to claim 1, wherein the resistance coefficient k in Step 2 is a modified resistance coefficient based on a recommended calculation formula for the lightning-induced overvoltage amplitude in a regulation, wherein an influence of the soil resistivity on the lightning-induced overvoltage is considered on the basis of the recommended calculation formula, and other equivalent methods are also used for correction or other influencing factors are considered for further correction.

3. The low-amplitude induced lightning hazard assessment method for the distribution network according to claim 1, wherein in Step 3, the step of partitioning the lightning-induced overvoltage amplitude U is primarily based on severity of hazard, comprising voltage level, insulation strength, and specific operation and maintenance conditions of the distribution network, with partition density and effectiveness depending on specific circumstances.

4. The low-amplitude induced lightning hazard assessment method for the distribution network according to claim 1, wherein the setting of the dangerous overvoltage threshold in Step 3 is not uniform across an entire line, and towers with weak insulation are considered separately.

5. The low-amplitude induced lightning hazard assessment method for the distribution network according to claim 1, wherein in Step 5, the issuing of the warning is proportional to the extent to which the overvoltage exceeds the dangerous overvoltage threshold.

6. The low-amplitude induced lightning hazard assessment method for the distribution network according to claim 1, wherein Step 5 to Step 6 utilize other human-machine interaction method.
